(19) United States
(12) Patent Application Publication
(10) Pub. No.: US 2007/0077771 A1
(43) Pub. Date: Apr. 5, 2007

(54) Method for producing buried micro-channels and micro-device comprising such micro-channels

(75) Inventors: Marc Plissonnier, Eybens (FR); Yves Fouillet, Voreppe (FR); Ludovic Poupinet, Sassenage (FR); Jean-Yves Laurent, Domene (FR)

Correspondence Address: OLIFF & BERRIDGE, PLC, P.O. BOX 19928, ALEXANDRIA, VA, 22320, US

(73) Assignee: COMMISSARIAT A I'ENERGIE ATOMIQUE, PARIS (FR)

(21) Appl. No.: 11/391,281

(22) Filed: Mar. 29, 2006

(30) Foreign Application Priority Data
Mar. 29, 2005 (FR) 0503029

(51) Int. Cl. H01L 21/31; H01L 21/469

(52) U.S. Cl. 438/758; 438/780

(57) ABSTRACT

The invention relates to a method for producing at least one buried micro-channel on a substrate consisting in applying and moving an optic radiation on a stacking in a predetermined direction. The stacking successively comprises a deformable absorbent thin layer and a thin-layer formed by a material able to locally release gas due to the action of a heating caused by the optic radiation. Local application of the optic radiation on the stacking forms a gas bubble, by local heating of the thin layer able to release gas, deforming the absorbent thin layer. Then the movement of the optic radiation extends the deformation of the absorbent thin layer in the direction of movement of the optic radiation and forms the buried micro-channel. The invention also relates to a micro-device for transportation of fluid and to a micro fuel-cell.

### BACKGROUND OF THE INVENTION

The invention relates to a method for producing at least one buried micro-channel on a substrate.

The invention also relates to a micro-device comprising at least one micro-channel designed to transport at least one fluid.

### State of the art

In a large number of fields such as the chemical, biological, biochemical and environmental analysis field, the medical field or quality control, the development of micro-technologies has enabled fluidic micro-systems to be produced forming laboratories on chips referred to as “lab-on-chip”. Such labs-on-chip enable the volumes of liquid to be analyzed to be miniaturized, while at the same time increasing the measuring speed and sensitivity. These micro-systems generally comprise channels designed to enable transport and/or chemical or biological reactions of different fluids. As represented in FIG. 1, one of the techniques for achieving the channels of a fluidic micro-system consists in patterning the side walls 1a and the bottom 1b of the channels 1 in a substrate 2. The substrate 2 is in general made of silicon or polymer. Thus, when the substrate 2 is made of silicon, the walls 1a and bottom 1b are generally obtained by techniques derived from micro-electronics, such as photolithography or etching whereas, for a polymer substrate 2, formation of the side walls la and bottom 1b of the channels 1 is obtained by molding. To prevent possible contaminations, a protective cover 3 is sealed onto the substrate 2 by means of seals 4 and it covers the channels 1. In addition, the seals 4 are arranged between two adjacent channels so as to insulate the latter from one another. Making channels in the substrate, by etching, photo-lithography or molding, does not however enable channels of very small dimensions, and in particular of nanometric size, to be obtained. Furthermore, it is difficult to perform efficient checking of the tightness of the protective cover 3, which may give rise to problems of contamination between the external environment and the channels and between adjacent channels. Another technique for fabricating channels consists in using a sacrificial material, i.e. a material able to be dissolved by chemical means. Thus, as represented in FIGS. 2 to 5, a sacrificial thin layer 5 is deposited on the free surface of a flat substrate 6, before being photolithographed and etched, so as to form raised patterned zones 5a. A thick layer 7 then totally covers the free surface of the substrate 6 and the raised zones 5a (FIG. 4), thus burying the raised zones 5a. Then each raised zone 5a is dissolved, enabling a space 8 to be free. Each space 8 is delineated by the thick layer 7 and the substrate 6 and then forms a buried micro-channel, i.e. a micro-fluidic duct generally provided with an inlet and an outlet. Such a technique does not however enable channels of very small sizes to be obtained. In addition, channels of complex shape cannot be achieved with this technique, for, with channels of complex shape, residues of non-dissolved materials potentially contaminant for the fluids are not eliminated.

Finally, both the techniques described use a patterning step, either of the substrate or of a sacrificial layer. This patterning step is, however, relatively costly.

It has also been proposed to achieve channels of nanometric sizes using silicon wires, obtained by chemical vapor deposition (CVD), with a diameter of a few nanometers. Each silicon wire is then surrounded by silicon oxide obtained by thermal oxidation growth. The silicon of the wire, sheathed by the silicon oxide, is then eliminated by a chemical solution, which releases a space delineated by the silicon oxide. This technique does however require individual handling of the silicon wires. In addition, the length of the silicon wires, and therefore of the channels, is relatively small for a micro-fluidic device. Finally, connection between different channels formed from the nano-wires and between a channel formed from a nano-wire and a channel obtained by another technique is not easy.

### Object of the invention

It is an object of the invention to provide a method that is easy to implement, that is inexpensive and that allows to obtain buried channels, with small dimensions, of any type of geometry and being easily connectable to one another and perfectly contamination-proof.

According to the invention, this object is achieved by the fact that the method comprises at least the following successive steps:
formation, on the surface of the substrate, of a stacking comprising a thin layer able to release gas due to the action of heating and an absorbent thin layer able to deform locally,
local application of an optic radiation on the stacking so as to form a gas bubble deforming the absorbent thin layer, at the interface between the two thin layers, by local heating of the thin layer able to release gas,
and movement of the optic radiation in a predetermined direction so as to extend the deformation of the absorbent thin layer in said direction and to form the buried micro-channel.

According to a development of the invention, the thin layer able to release gas is made of SiC_{xO}_{y}:H, advantageously with x comprised between 0.8 and 1.4 and y comprised between 1.2 and 1.4.

More particularly, the thin layer of SiCₓO_{y}:H can be obtained by chemical vapor deposition by means of a precursor chosen from the organo-silanes.

According to a particular embodiment, formation of the buried micro-channel is followed by an additional step during which an optic radiation is locally applied to the stacking so as to pierce the deformed absorbent thin layer and to form an opening in the buried micro-channel.

It is also an object of the invention to provide a micro-device comprising at. least one micro-channel designed to transport at least one fluid, presenting very small dimensions, of any type of geometry and perfectly contamination-proof.

According to the invention, this object is achieved by the fact that the micro-channel of such a micro-device is a buried micro-channel on a substrate implemented by a method for producing as described above.

According to a development of the invention, the micro-channel is designed to transport a fluid containing chemical or biological elements.

According to another development of the invention, the micro-device constitutes a micro fuel-cell comprising at least:
a stacking formed by first and second electrodes between which electrodes a membrane formed by an ion conducting polymer is arranged,
and at least one series of buried micro-channels designed to supply said micro fuel-cell with reactive fluid and provided with at least one opening to enable supply of reactive fluid.

Such a micro fuel-cell presents the advantage of being compact and of having improved global performances compared with micro fuel-cells according to the prior art.

### BRIEF DESCRIPTION OF THE DRAWINGS

Other advantages and features will become more clearly apparent from the following description of particular embodiments of the invention given as non-restrictive examples only and represented in the accompanying drawings, in which:

FIG. 1 schematically represents, in cross-section, an embodiment of micro-channels in a substrate, according to the prior art.

FIGS. 2 to 5 schematically represent, in cross-section, a method for producing buried micro-channels on a substrate, according to the prior art.

FIGS. 6 to 9 schematically represent, in cross-section, different steps of producing buried micro-channels on a substrate, according to the invention.

FIG. 10 is a perspective view of the stacking represented in cross-section in FIG. 9 and comprising micro-channels obtained according to the invention.

FIG. 11 represents, in cross-section, an additional step of producing buried micro-channels on a pattern according to FIG. 10.

FIG. 12 represents the variation of the height of a gas bubble versus the power of an applied optic radiation and versus the thickness of a layer of SiCₓO_{y}:H enabling formation of the gas bubble.

FIGS. 13 to 16 schematically represent, in cross-section, the different steps of producing a micro fuel-cell comprising micro-channels obtained according to the invention.

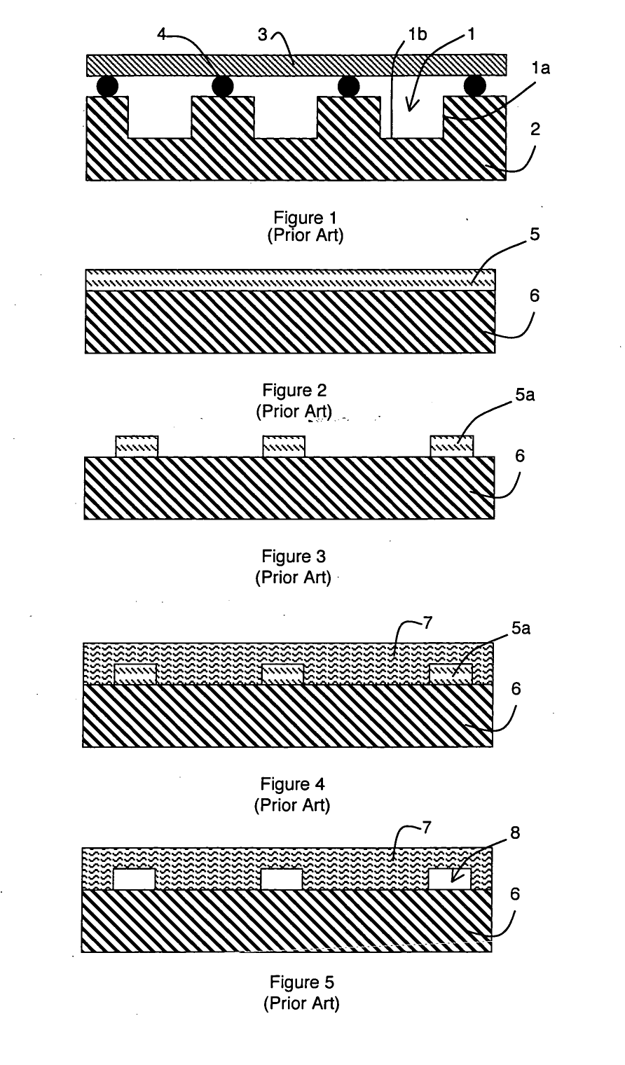

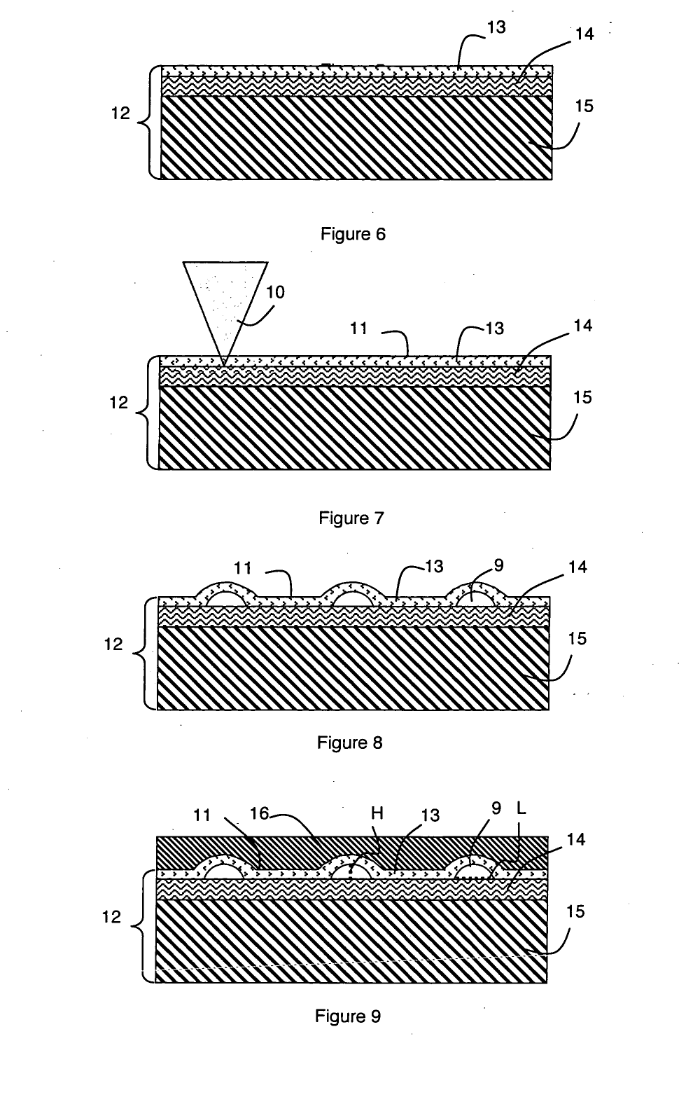

### DESCRIPTION OF THE PARTICULAR EMBODIMENTS

As illustrated in a particular embodiment represented in FIGS. 6 to 10, buried micro-channels 9 are achieved by applying and moving an optic radiation 10, such as a focused laser beam, in a predetermined direction on a free surface 11 of a stacking 12 successively comprising:
a deformable thin layer 13 able to absorb at least a part of the optic radiation 10 so as to create an temperature increase also called heating
a thin layer 14 formed by a material able to locally release gas due to the action of said heating
and a preferably flat substrate 15.

Thus in FIG. 6, the stacking 12 is formed by previously depositing the thin layer 14 on a free surface of the substrate 15, and then covering this layer with the deformable and absorbent thin layer 13. Then, as represented in

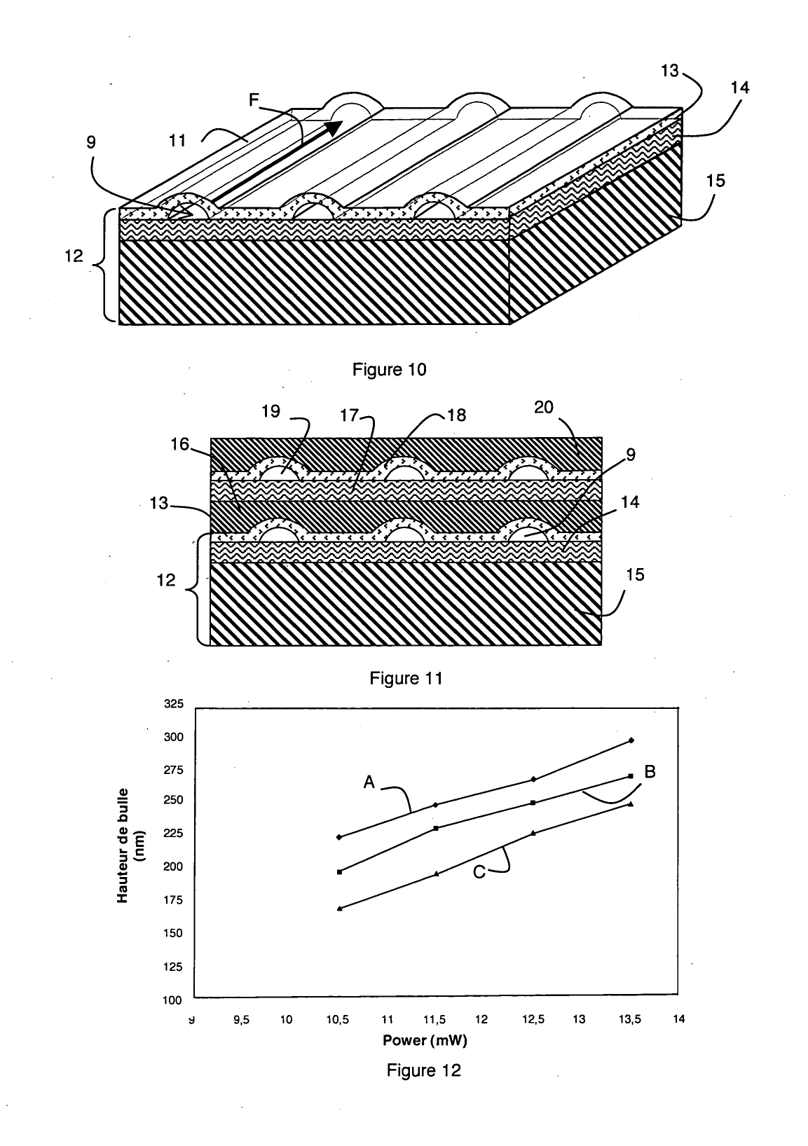

FIG. 7, the optical radiation 10 is locally applied on the stacking 12, from the free surface of the absorbent thin layer 13 through to the inside of the stacking. The free surface of the absorbent thin layer 13 then forms the free surface 11 of the stacking 12 designed to receive the optic radiation 10.

The optic radiation 10 is absorbed by the stacking 12 so as to cause local heating in the stacking and, more particularly, in the thin layer 14 able to release gas. This absorption can be performed in particular by the thin layer 13, chosen for its ability to absorb at least a part of the optic radiation 10. The thin layer 13 is also called absorbent thin layer 13, able to deform locally.

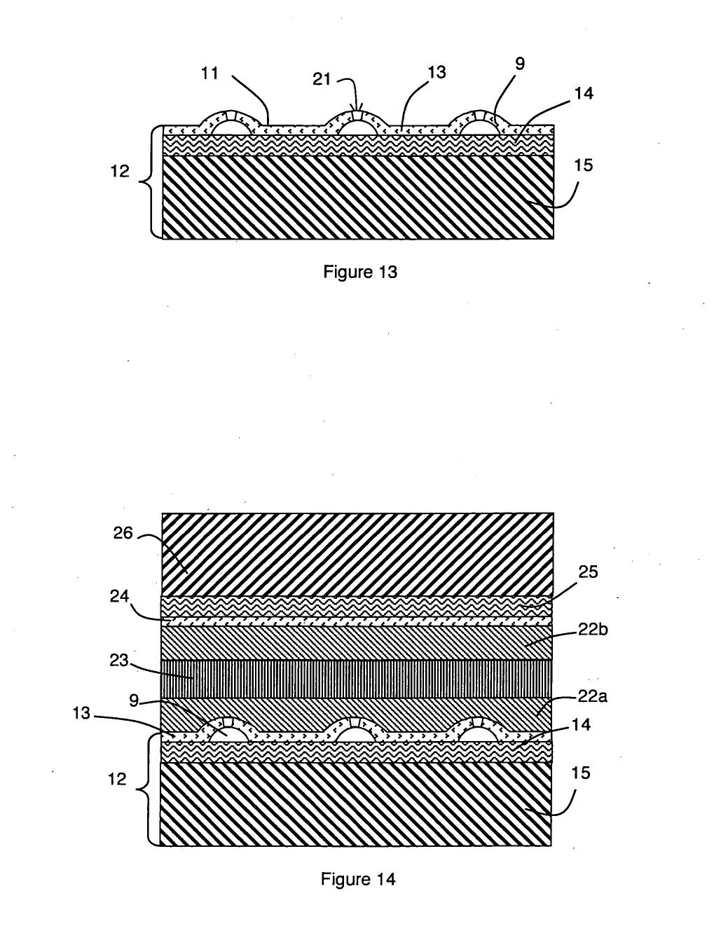

Local heating of the thin layer 14 has the effect of making a gas bubble form at the interface between the thin layers 13 and 14 and causes a local deformation of the absorbent thin layer 13 by mechanical action. The optic radiation 10 is then moved in a predetermined direction so as to extend formation of gas bubbles at the interface between the two thin layers in continuous manner in the direction of movement. In FIG. 10, the direction of movement of the optic radiation 10 is represented by the arrow F. This movement then enables the deformation of the absorbent layer 13 to be extended As illustrated in FIGS. 8 to 10, the deformed zone of the absorbent layer 13 then delineates a space with the surface of the thin layer 14 that has released gas, the whole forming a buried duct or channel 9.

The invention is not limited to achieving a buried channel on a substrate. A plurality of buried channels can in fact be simultaneously or successively formed in the stacking. For example, several optic radiations can be applied and moved simultaneously. In an alternative embodiment, the optic radiation 10, after it has formed a first buried channel 9, can be positioned at another location, before being applied again on the stacking and moved in a second specific direction to form a second buried channel 9.

Thus, in FIGS. 8 and 10, the stacking comprises three buried channels 9 formed, in their length, in three predetermined parallel directions. The predetermined directions may also not be parallel so that the buried channels cross and form a lattice.

Once the micro-channels 9 have been formed, an optic radiation such as a laser beam can be applied one or more times on the free surface of the absorbent layer 13, at the level of the deformed zones, to pierce said absorbent layer 13. This operation enables one or more openings to be formed in a buried micro-channel 9, which openings can for example be the inlet and/or outlet of the channel. The operation designed to pierce the absorbent layer 13 can for example be performed either by increasing the power of the optic radiation 10 used to form the micro-channels 9 or by extending the exposure time or by repeating the exposure of the optic radiation 10 on the stacking 12.

As represented in FIG. 9, once the buried channels 9 have been formed, a protective layer 16 may be deposited on the free surface 11 of the absorbent thin layer 13 so as to consolidate the channels 9 formed. The protective layer 16 is for example made from silicon nitride or silicon oxide and it can be deposited by spin coating or by chemical vapor deposition (CVD), possibly plasma enhanced (PECVD). It enables a stacking 12 to be obtained comprising two flat free surfaces. When the channels 9 present one or more openings, the protective layer 16 is preferably itself pierced in alignment, i.e. opposite the opening or openings of the channels

The height H and width L of a channel 9 are represented in FIG. 9. More particularly, to obtain a micro-channel 9 having a height H of 200 nm, a focused laser beam with a power density ranging from 23 mW/μm² to 32 mW/μm² is generally used, and the thin layer 14 generally has a thickness comprised between 10 nm and 60 nm. Moreover, the length of a channel 9 corresponds to the distance covered by the optic radiation 10.

In an alternative embodiment represented in FIG. 11, the different steps of the method for producing the micro-channels 9 can be repeated on the free surface of the protective layer 16. This enables a pattern comprising at least two superposed series of micro-channels to be obtained. A stacking such as the one represented in FIG. 10 and provided with a first series of channels 9 is thus successively covered:
by an additional thin layer 17 formed by a material able to locally release gas,
and by an additional absorbent thin layer 18.

After an optic radiation has been applied and moved on the free surface of the additional absorbent thin layer 18, a second series of buried channels 19 is formed. The whole assembly is then covered with a protective layer 20 designed to consolidate the second series of micro-channels 19.

The material able to release gas and forming, in FIGS. 8 and 11, the thin layer or layers 14 and 17 is chosen such that its chemical composition enables a sufficient quantity of gas to be given off locally to form a bubble, while keeping a mechanical strength guaranteeing the stability of the stacking. The material able to release gas is more particularly a polysiloxane-based material obtained by chemical vapor deposition (CVD), preferably plasma enhanced (PECVD), using a precursor chosen from the organo-silanes. The material able to release gas is preferably a carbon-doped hydrogenated amorphous silicon oxide of the SiCₓO_{y}:H, type, preferably with x comprised between 0.8 and 1.4 and y comprised between 1.2 and 1.4. More particularly, to form a layer of SiCₓO_{y}:H, the organo-silane precursor is formed by cyclic octamethyltetrasiloxane (OMCTS) or one of its derivatives, and it is mixed with helium. The thickness of the thin layers 14 and 17 is preferably comprised between 10 nm and 60 nm. In addition, to obtain a sufficient gas release, the SiCₓO_{y}:H deposition conditions are preferably chosen so as to obtain a thin layer of SiCₓO_{y}:H having a conformation or a pattern partially preserving the pattern of the cyclic OMCTS precursor used.

Using a carbon-doped hydrogenated amorphous silicon oxide to form a thin layer designed to generate gas also presents the advantage of obtaining a micro-channel having a hydrophilic bottom wall. The surface of the zone having released gas due to the action of the optic radiation 10 in fact forms the bottom wall or a bottom of the micro-channel 9. However, when the carbon-doped hydrogenated amorphous silicon oxide is heated by the optic radiation 10, it releases not only gas but it also becomes hydrophilic, which enables an aqueous solution to be able to enter and possibly move in the channel.

The absorbent thin layer or layers 13 and 18 are deformable, i.e. they are able to deform locally under the effect of a mechanical action exerted on said absorbent thin layer or layers. They are for example formed by a chemical compound chosen from a tellurium and tin alloy (SnTe) or a tellurium and zinc alloy (ZnTe). They have for example a thickness of a few tens of nanometers.

For example, a thin layer 14 of SiCₓO_{y}:H, with a thickness of 20 nm is deposited on a silicon or polycarbonate substrate by PECVD deposition using a plasma excited by a capacitive discharge at 13.56 Mhz. A low-frequency or radio-frequency generator then enables a plasma discharge to be made near the substrate and the cyclic OMCTS precursor, mixed with helium, is injected into the deposition chamber at reduced pressure, for example at 0.2 mBar. The plasma power density is for example 0.81 W/cm and the precursor flowrate input to the chamber is for example 0.273 cm³/min. The material of the deposited thin layer 14 has, more particularly, the following formula: SiC_{0.2}O_{0.3}H_{0.55}.

An absorbent thin layer 13, made of SnTe and having a thickness of 20 nm, is then deposited on the thin layer 14 and is then irradiated by a focused laser beam having a power density comprised between 23 mW/μm² and 32 mW/μm². The laser beam source is for example a focused laser diode with a microscope lens. The focused laser beam is then moved on the free surface of the absorbent thin layer 13. Once the micro-channel or micro-channels have been formed, a protective layer, for example made of SiO₂ or Si₃N₄, may be deposited on the free surface of the absorbent layer 13.

The quantity of gas emitted by the thin layer or layers able to generate gas also depends on the power density of the optic radiation 10. For illustration purposes, in FIG. 12, curves A to C illustrate the variation of the height of a gas bubble achieved in a stacking such as the one represented in FIG. 6, versus the power of the laser beam used, for thicknesses of SiCₓO_{y}:H thin layer 14 respectively of 20, 40 and 60 nm. The deformable absorbent layer 13 is made of SnTe. It can be observed that the height of the gas bubble generated increases when the power of the laser beam increases. Moreover, the height of the gas bubble and therefore the height H of the channel 9 is at its maximum when the thickness of the thin layer 14 is 20 nm. Buried micro-channels of very small dimensions, able to be controlled and relatively inexpensive to achieve, can be obtained on a substrate by the method for producing according to the invention. Such a method is more particularly suitable for achieving micro-devices equipped with micro-channels designed to transport fluids containing, for example, chemical or biological elements such as the fluidic micro-devices used for example for chemical or biological analysis. More particularly, it is possible, on account of the narrowness of the optic radiation used, to achieve micro-channels presenting a width L comprised between 0.1 μm and 2 μm and a height H comprised between 0.06 μm and 0.2 μm. In addition, a stacking can comprise a high density of buried channels, and it is very easy to connect them to one another and/or with channels achieved by techniques according to the prior art. As the channels are buried, there is moreover no risk of contamination between two independent channels. Furthermore, the optic radiation enabling the micro-channels to be formed can move in any direction, which enables any type of micro-channels, and more particularly non-linear micro-channels, to be obtained. This is particularly interesting for producing micro-systems for chemical or biological analysis. It is also possible to achieve a chromatographic column or a biochemical reactor requiring a large interaction surface between a solid and a liquid. In this case, it is possible to achieve crossing micro-channels, in particular to form a sort of labyrinth.

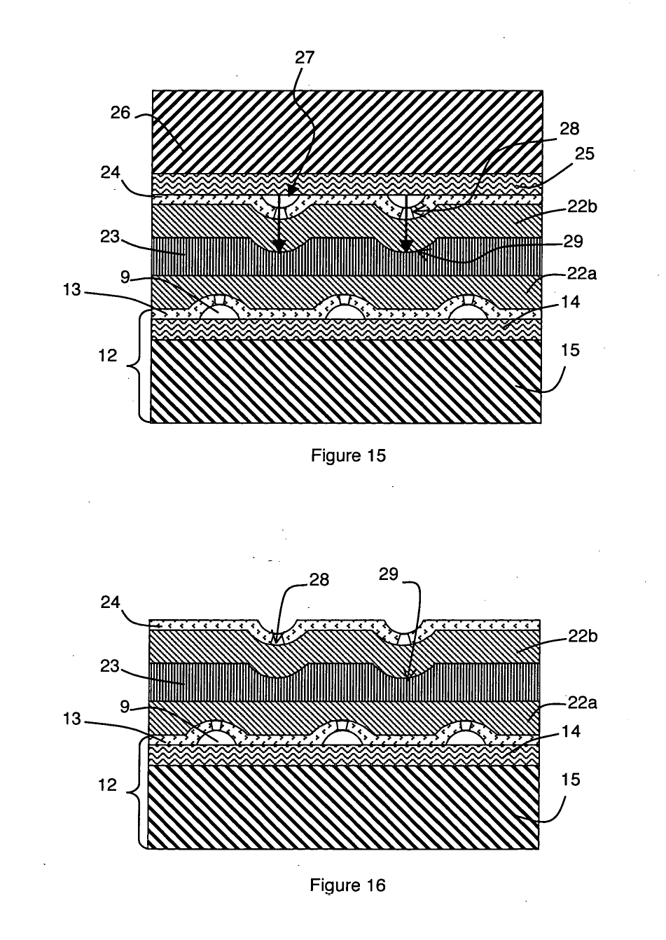

As represented in FIGS. 13 to 16, the method for producing buried micro-channels can also be used in fabrication of a micro fuel-cell. A stacking containing a series of buried micro-channels as represented in FIG. 8 can thus act as the basis for producing a fuel-cell. Once the micro-channels 9 have been formed, an optic radiation such as a laser beam can be applied on the free surface of the absorbent layer 13 to pierce said absorbent layer 13. This operation enables an opening 21 to be formed in the absorbent layer 13. The operation can be repeated several times so as to form a succession of openings 21 located along a micro-channel 9. This opening 21 can also be extended over the whole length of a micro-channel 9, by moving the laser beam.

As represented in FIG. 14, a successive stacking of thin layers, of the EME (Electrode-Membrane-Electrode) type, is deposited on the free surface of the absorbent thin layer 13. The EME stacking comprises a first and second electrode 22a and 22b between which electrodes a membrane 23 formed by an ion conducting polymer is arranged. The polymer of the membrane 23 is for example Nafion® deposited by spin coating whereas the first and second electrodes 22a and 22b are for example platinum-plated carbon powder, i.e. a catalyzer in the form of carbon powder mixed with active platinum particles. The channels 9 formed at the interface of the absorbent thin layer 13 and of the thin layer 14 and provided with openings 21 then form a first series of micro-channels supplying reactive fluids to the first electrode 22a.

Then an additional absorbent thin layer 24, an additional thin layer 25 able to generate gas and a rigid substrate 26 transparent to optic radiation are successively arranged on the free surface of the second electrode 22b. The additional absorbent layer 24 is then deformed and pierced by the action of an optic radiation originating from the free surface of the substrate 26 so as to form a second series of buried micro-channels 27 provided with openings 28 repeated over the whole length of the channels. Deformation of the additional absorbent layer 25 also causes a local compression 29 of the second electrode 22b on the membrane 23 in localized manner. This is particularly interesting in so far as it multiplies the contact points between the catalyzer of the second electrode 22b and the membrane 23. This then increases the efficiency and the global performances of the fuel cell.

For example, the first electrode 22a can be an anode so that the first series of channels 9 act as channels supplying the anode with hydrogen. Moreover, the absorbent thin layers 13 and 25 form the current collectors of the fuel cell. To improve their electrical characteristic, these absorbent layers can be covered by a layer formed by a good electrical conducting material such as a noble metal, for example gold. The substrate 26 and the additional thin layer 25 can be removed, for example by chemical dissolution (FIG. 16). In this case, the fuel cell only comprises one series of supply channels 9. If the substrate 26 and additional thin layer 25 are not removed, the fuel cell will comprise a second series of reactive fluid supply channels arranged on the side where the second electrode 22b is situated.

A fuel cell such as the one represented in FIG. 16 is very compact, with a size of a few micrometers, and with a much greater efficiency than that obtained with fuel cells according to the prior art.

1. Method for producing at least one buried micro-channel on a substrate comprising at least the following successive steps:
formation, on the surface of the substrate, of a stacking comprising a thin layer able to release gas due to the action of heating and an absorbent thin layer able to deform locally,
local application of an optic radiation on the stacking so as to form a gas bubble deforming the absorbent thin layer, at the interface between the two thin layers, by local heating of the thin layer able to release gas,
and movement of the optic radiation in a predetermined direction so as to extend the deformation of the absorbent thin layer in said direction and to form the buried micro-channel.

2. Method according to claim 1, wherein the thin layer able to release gas is made of SiCₓO_{y}:H.

3. Method according to claim 2, wherein x is comprised between 0.8 and 1.4 and y is comprised between 1.2 and 1.4.

4. Method according to claim 2, wherein the thin layer of SiCₓO_{y}:H is obtained by chemical vapor deposition by means of a precursor selected from the group consisting of organo-silanes.

5. Method according to claim 4, wherein the chemical vapor deposition is a plasma enhanced chemical vapor deposition.

6. Method according to claim 4, wherein the organo-silane precursor is formed by cyclic octamethyltetrasiloxane or one of its derivatives and that it is mixed with helium.

7. Method according to claim 1, wherein the thin layer able to release gas has a thickness comprised between 10 nm and 60 nm.

8. Method according to claim 1, wherein the absorbent thin layer is formed by a compound selected from the group consisting of a tellurium and tin alloy, and a tellurium and zinc alloy.

9. Method according to claim 1, wherein the optic radiation is a focused laser beam.

10. Method according to claim 1, wherein the micro-channel has a width- of less than 5 μm and a height of less than 5 μm.

11. Method according to claim 1, wherein, once the micro-channel has been formed, a thin protective layer is deposited on a free surface of the absorbent thin layer.

12. Method according to claim 1, wherein formation of the buried micro-channel is followed by an additional step during which an optic radiation is applied locally on the stacking so as to pierce the deformed absorbent thin layer and to form an opening in the buried micro-channel.

13. Micro-device comprising at least one micro-channel designed to transport at least one fluid, wherein the micro-channel is a buried micro-channel on a substrate implemented by the method for producing according to claim 1.

14. Micro-device according to claim 13, wherein the micro-channel is designed to transport at least one fluid containing chemical or biological elements.

15. Micro-device according to claim 13, constituting a micro fuel-cell comprising at least:
a stacking formed by first and second electrodes between which electrodes a membrane formed by an ion conducting polymer is arranged,
and at least one series of buried micro-channels designed to supply said micro fuel-cell with reactive fluid and provided with at least one opening to enable supply of reactive fluid.
